(19) United States
(12) Patent Application Publication
(10) Pub. No.: US 2008/0203535 A1
(43) Pub. Date: Aug. 28, 2008

(54) SEMICONDUCTOR DEVICE

(76) Inventors: Masaaki NODA, Shiga (JP); Keiki Okamoto, Toyama (JP)

Correspondence Address: MCDERMOTT WILL & EMERY LLP, 600 13TH STREET, N.W., WASHINGTON, DC, 20005-3096, US

(21) Appl. No.: 12/038,734

(22) Filed: Feb. 27, 2008

(30) Foreign Application Priority Data
Feb. 27, 2007 (JP) 2007-048026

(51) Int. Cl. H01L 29/739

(52) U.S. Cl. 257/579; 257/E29.201; 257/487

(57) ABSTRACT

A semiconductor device relating to the present invention comprises a base layer of an N-type impurity region. In the base layer, trenches are provided. In the each trench, a gate insulating film and a gate electrode are formed. A body layer of a P-type impurity region is formed in contact with the trenches, and in parallel adjacent to the base layer. On the main surface of the body layer, an emitter layer of an N-type impurity region is provided. On the main surface of the body layer, a contact layer of a P-type impurity region is provided spaced from the trenches. The emitter layer and the contact layer are exposed in different regions on the main surface of the body layer. A buried layer of a P-type impurity region is formed spaced from the trenches in closer to the base layer than to the contact layer in the body layer.

### CROSS-REFERENCE TO RELATED APPLICATION

The present application claims the benefit of Japanese Patent Application No. 2007-48026 filed Feb. 27, 2007, the subject matter of which is incorporated herein by reference.

### BACKGROUND OF THE INVENTION

1. Field of the Invention

This invention relates to a semiconductor device, and more particularly to an insulated gate bipolar transistor.

2. Description of the Related Art

Insulated gate bipolar transistors (IGBTs) are conventionally used for power semiconductor devices. It is a well-known structure wherein an IGBT has trenches filled with gate electrodes on a surface of a substrate (for example, see Japanese Laid-Open Patent Publication No. 11-345969).

FIG. 15 is a plan view showing a conventional structure of an IGBT wherein trenches filled with gate electrodes on a surface of a substrate are provided. FIG. 16 is a cross-sectional view taken along a line A-A in FIG. 15, and FIG. 17 is a cross-sectional view taken along a line B-B in FIG. 15. FIGS. 15 to 17 are schematic views and the components are not shown in their actual scale ratios.

As shown in FIGS. 16 and 17, in the conventional IGBT, there is provided a base layer 105 consisting of a low concentration N-type impurity region. A collector layer 107 consisting of a high concentration P-type impurity region is formed below the base layer 105 with a buffer layer 106 consisting of a high concentration N-type impurity region interposed therebetween. A collector electrode 112 is connected to the collector layer 107.

In the meantime, on top of the base layer 105, there is provided a body layer 103 consisting of a P-type impurity region. In the body layer 103, a plurality of trenches 121, which reach the base layer 105 through the body layer 103, is formed with a given interval width W. The each trench 121 is filled with a gate electrode 109 formed of polysilicon and the like with a gate insulating film 110 interposed therebetween. As shown in FIG. 15, the each gate electrode 109 (trench 121) is continuously formed in a direction perpendicular to the sheets in FIGS. 16 and 17.

As shown in FIGS. 15 and 16, emitter layers 104 consisting of high concentration N-type impurity regions are formed in contact with the trenches 121 in portions on the surface of the body layer 103. As shown in FIG. 15, the each emitter layer 104 is arranged intersecting with the gate electrodes 109.

As shown in FIGS. 15 and 17, in portions on the surface of the body layer 103, contact layers 101 consisting of high concentration P-type impurity regions are formed in contact with the trenches 121. As shown in FIG. 15, the each contact layer 101 is provided intersecting with the gate electrodes 109. The emitter layers 104 and the contact layers 101 are alternately arranged.

FIG. 18 is a plan view showing a plane structure of the gate electrodes 109 and the contact layers 101 only in the IGBT. As showing FIG. 18, the contact layers 101 are not formed in regions where the emitter layers 104 are formed.

In the IGBT shown in FIGS. 15 to 17, an emitter electrode 111 which is electrically connected to both the emitter layers 104 and the contact layers 101 is provided on the top of the emitter layers 104 and the contact layers 101. Oxide films 108 are interposed between the each gate electrode 109 and the emitter electrode 111 so that the each gate electrode 109 and the emitter electrode 111 are electrically insulated.

In the IGBT having the above-described structure, the N-type emitter layer 104, the P-type body layer 103 and the N-type base layer 105, which are formed along the each trench 121, constitute an N-channel MOS transistor (see FIG. 16). The P-type contact layer 101, the P-type body layer 103, the N-type base layer 105, the N-type buffer layer 106 and the P-type collector layer 107 constitute a PNP bipolar transistor (see FIG. 17). The IGBT is operated by combined operations of the MOS and the PNP transistors.

For example, in a state that negative potential is applied to the emitter electrode 111, and concurrently positive potential is applied to the collector electrode 112, the positive potential, which is larger than that of being applied to the emitter electrode 111, is applied to the each gate electrode 109. Under this state, inversion layer is formed on the surface of the P-type body layer 103 to which the each gate insulting film 110 contacts. Thus, the MOS transistor turns on-state and electron current flows in the MOS transistor. FIG. 19 illustrates such electron current and an equivalent circuit corresponding to a cross-sectional structure shown in FIG. 16.

As shown in FIG. 19, electron current flows from the collector electrode 112 to the emitter electrode 111 passing through a PN junction diode composed of the P-type collector layer 107 and the N-type buffer layer 106, the N-type base layer 105, the N-type inversion layer (a channel of the MOS transistor) formed on the surface of the P-type body layer 103 to which the each gate insulating film 110 contacts and the N-type emitter layer 104.

The electron current has a function as a base current of the PNP transistor. Namely, when the electron current flows, the PNP transistor turns on-state and hole current flows in the PNP transistor. FIG. 20 illustrates such hole current and an equivalent circuit corresponding to the cross-sectional structure shown in FIG. 17.

As shown in FIG. 20, hole current flows from the collector electrode 112 to the emitter electrode 111 passing through the P-type collector layer 107, the N-type buffer layer 106, the N-type base layer 105, the P-type body layer 103 and the P-type contact layer 101.

In the IGBT, when electron current flows in the MOS transistor, the base current is provided to the PNP transistor and the PNP transistor turns on-state. Therefore, in the IGBT, on-state and off-state of the PNP transistor is switched by switching on-state and off-state of the each MOS transistor by controlling a voltage applied to the each gate electrode 109.

### SUMMARY OF THE INVENTION

According to the above-described conventional IGBT, as shown in FIG. 21, the P-type collector layer 107, the N-type buffer layer 106, the N-type base layer 105, the P-type body layer 103 and N-type emitter layer 104 constitute a parasitic thyristor having a PNPN structure.

As described above, in the IGBT, the each N-type emitter layer 104 is connected to the emitter electrode 111 on a main surface of the substrate. The P-type body layer 103 as well is connected to the emitter electrode 111 on the main surface via the contact layer 101. As a result, when hole current in the PNP transistor is small, potential in the emitter layer 104 and potential in the body layer 103 are almost the same, and the PN junction diode composed of the emitter layer 104 and the body layer 103 does not turn on-state, and thereby the parasitic thyristor does not turn on-state.

On the contrary, when hole current becomes large in the PNP transistor, deeper the position from the main surface of the P-type body layer 103 is, higher the potential rises due to resistance component of itself. Then, when a potential difference of approximately 0.7 V between the body layer 103 and the emitter layer 104 is generated as the potential rises in the body layer 103, the PN junction diode composed of the body layer 103 and the emitter layer 104 turns on-state, and thereby the parasitic thyristor turns on-state.

When the parasitic thyristor turns on-state, the hole current flows in the parasitic thyristor and the potential in the body layer 103 further rises due to the hole current as shown in FIG. 21. Then, eventually, destruction will be occurred in the IGBT. For that reason, it is demanded that the threshold value of the hole current by which the parasitic thyristor turns on-state should be large.

In addition, in the structure of the conventional IGBT, when potential is applied to the collector electrode 112 and the emitter electrode 111 in order to evaluate an emitter-collector breakdown voltage, electric fields are concentrated at the bottom corners of the trenches 121. FIG. 22 is a schematic view illustrating such concentration of the electric fields. Edges of a depletion layer generated in a boundary of the N-type base layer 105 and the P-type body layer 103 are shown by broken lines in FIG. 22.

When the potential is applied to the collector electrode 112 and the emitter electrode 111, as shown in FIG. 22, the depletion layer extends from the boundary of the base layer 105 and the body layer 103 toward the base layer 105 and the body layer 103. The depletion layer extends toward the base layer 105 along a shape of the each trench 121. At this time, in the base layer 105 and the body layer 103, electric fields are concentrated at the bottom corner of each trench 121 (shown by dotted lines) because of the curvature of the depletion layer at the bottom corner of the trench 121 is large.

Consequently, in the above-described conventional IGBT, when potential is applied in order to evaluate the emitter-collector breakdown voltage of the IGBT, breakdown is firstly occurred in the vicinity of the gate insulating film 110. When the breakdown is occurred, hot carriers generated by the breakdown enter the gate insulating film 110. Therefore, according to the conventional IGBT, when potential is applied in order to evaluate the emitter-collector breakdown voltage of the IGBT in delivery inspections and the like, degradation of reliability and destruction of the gate insulating film 110 are subject to be occurred by carrier-trap in the gate insulating film 110.

The present invention is proposed by taking the above problems into consideration and has an object to provide a semiconductor device with an IGBT having a high ruggedness.

The present invention employs following technical methods in order to solve the above-described problems. Firstly, the present invention is on the premise that a semiconductor device includes an insulated gate bipolar transistor. A semiconductor device according to the present invention is provided with a base layer of a first conductivity type impurity region. A trench formed region is provided within the base layer. Within the trench formed region, a gate insulating film and a gate electrode are formed. Within the base layer, a body layer of a second conductivity type impurity region is formed in contact with the trench formed region. On the main surface of the body layer, an emitter layer of the first conductivity type impurity region is provided. Further, on the main surface of the body layer, a contact layer of the second conductivity type impurity region is provided spaced from the trench formed region. The emitter layer and the contact layer are exposed in different regions on the surface of the body layer. A buried layer of the second conductivity type impurity region is formed spaced from the trench formed region in the body layer. An impurity concentration peak position of the buried layer is deeper than that of the contact layer.

In this structure, the buried layer can be disposed in a state that a breakdown voltage in a PN junction composed of the body layer wherein the buried layer is formed and the base layer is lower than a breakdown voltage between a bottom corner of the trench formed region formed within the base layer and the base layer.

Further, the following structure can be applied to the above described plane structure of the main surface, for example. A plurality of trench formed regions is disposed spaced from one another. The contact layer is disposed in each space between the trench formed regions without intersecting with each of the trench formed regions. The buried layer is disposed in each space between the trench formed regions without intersecting with each of the trench formed regions. Then, a plurality of the emitter layers is disposed spaced from one another in a direction intersecting with the trench formed regions, the contact layer and the buried layer.

Furthermore, the following structure can be applied to the above described plane structure of the main surface. A plurality of the trench formed regions is disposed spaced from one another. The buried layer is disposed in each space between the trench formed regions without intersecting with the trench formed regions. A plurality of the emitter layers is disposed spaced from one another in a direction intersecting with the trench formed regions and the buried layer. The contact layer is disposed in each space between the trench formed regions and between the emitter layers.

In the meantime, another semiconductor device including an insulated gate bipolar transistor in accordance with the present invention provides a base layer of a first conductivity type impurity region. A trench formed region is provided in the base layer. A gate insulating film and a gate electrode are formed within the trench formed region. A body layer of a second conductivity type is formed in contact with the trench formed region within the base layer. On the main surface of the body layer, an emitter layer of the first conductivity type impurity region is provided. Further, on the main surface of the body layer, a contact layer of the second conductivity type impurity region is provided in a state that the contact layer is thinner in thickness than the emitter layer and has a surface concentration smaller than the emitter layer. The emitter layer and the contact layer are exposed on the different regions on the main surface of the body layer. A buried layer of the second conductivity type is formed spaced from the trench formed region, and is positioned closer to the base layer than to the contact layer within the body layer.

In this structure as well, the buried layer can be disposed in a state that a breakdown voltage of a PN junction composed of the body layer wherein the buried layer is formed and the base layer is lower than a breakdown voltage between a bottom corner of trench formed region formed within the base layer and the base layer.

Further, the following structure can be applied to a plane structure of the main surface, for example. A plurality of the trench formed regions is disposed spaced from one another. The buried layer is disposed in each space between the trench formed regions without intersecting with each of the trench formed regions. A plurality of emitter layers is disposed spaced from one another in a direction intersecting with the trench formed regions and the buried layer. The contact layer is disposed in the region surrounded by the trench formed regions and the emitter layers, and in the region including a portion of the emitter layer or the entire emitter layer.

The above-described structure can be applied to a semiconductor device having a structure that a collector layer of the second conductivity type impurity region is formed on an opposite side of the body layer. While, the above-described structure can be applied to a semiconductor device having a structure that a collector layer of the second conductivity type impurity region is formed apart from the body layer on the same side of the body layer. In this case, an element isolation film is provided adjacent to the base layer on the opposite side of the body layer in the depth direction.

According to the present invention, potential rise in a body layer during an operation of an insulated gate bipolar transistor is suppressed without affecting a threshold voltage of the IGBT. As a result, it is suppressed that a parasitic thyristor in an insulated gate bipolar transistor turns on-state, and thereby a semiconductor device having a high ruggedness to meet withstand requirements can be realized. Further, when evaluating a collector-emitter breakdown voltage in the insulated gate bipolar transistor, a portion where breakdown is firstly occurred is arranged to a PN junction composed of a body layer and a base layer, and thereby occurrence of degradation of electric characteristics and destruction are prevented.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a semiconductor device in accordance with First Embodiment of the present invention.

FIG. 2 is a cross-sectional view showing a semiconductor device in accordance with First Embodiment of the present invention.

FIG. 3 is a cross-sectional view showing a semiconductor device in accordance with First Embodiment of the present invention.

FIG. 4 is a plan view showing a semiconductor device in accordance with First Embodiment of the present invention.

FIG. 5 is a diagram showing a profile for impurity concentration of a buried layer in accordance with First Embodiment of the present invention.

FIG. 6 is a view showing portions where breakdown is occurred in a semiconductor device in accordance with First Embodiment of the present invention.

FIG. 7 is a plan view showing a modified example of a semiconductor device in accordance with First Embodiment of the present invention.

FIG. 8 is a plan view showing a modified example of a semiconductor device in accordance with First Embodiment of the present invention.

FIG. 9 is a plan view showing a semiconductor device in accordance with Second Embodiment of the present invention.

FIG. 10 is a cross-sectional view showing a semiconductor device in accordance with Second Embodiment of the present invention.

FIG. 11 is a cross-sectional view showing a semiconductor device in accordance with Second Embodiment of the present invention.

FIG. 12 is a plan view showing a semiconductor device in accordance with Second Embodiment of the present invention.

FIG. 13 is a cross-sectional view showing a semiconductor device in accordance with Third Embodiment of the present invention.

FIG. 14 is a cross-sectional view showing a semiconductor device in accordance with Third Embodiment of the present invention.

FIG. 15 is a plan view showing a conventional IGBT.

FIG. 16 is a cross-sectional view showing a conventional IGBT.

FIG. 17 is a cross-sectional view showing a conventional IGBT.

FIG. 18 is a plan view showing a conventional IGBT.

FIG. 19 is a view illustrating electron current during normal operation of a conventional IGBT.

FIG. 20 is a view illustrating hole current during normal operation of a conventional IGBT.

FIG. 21 is a view illustrating an operation of a parasitic thyristor of a conventional IGBT.

FIG. 22 is a view showing portions where breakdown is occurred in a conventional IGBT.

### DETAILED DESCRIPTION OF PREFERRED EMBODIMENTS

Embodiments of the present invention will be described in detail hereinafter with reference to the drawings. In the following embodiments, the present invention is specified as a semiconductor device including an IGBT having N-channel MOS and PNP transistors. The following descriptions are applied as well to a semiconductor device including an IGBT having P-channel MOS and NPN transistors by reversing a conductivity type of each impurity region.

### First Embodiment

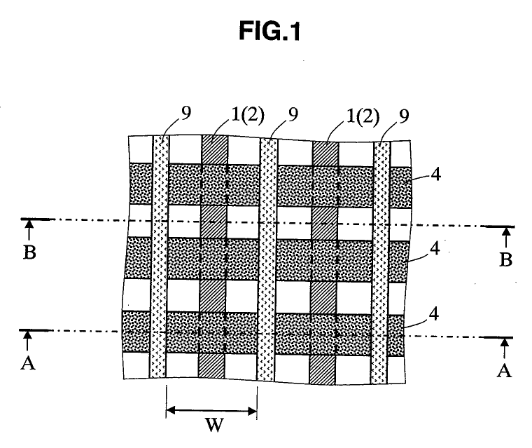

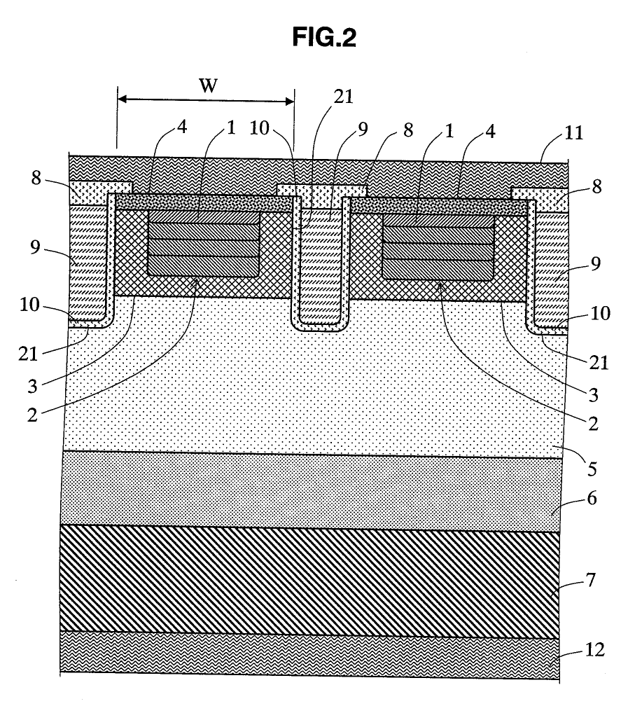

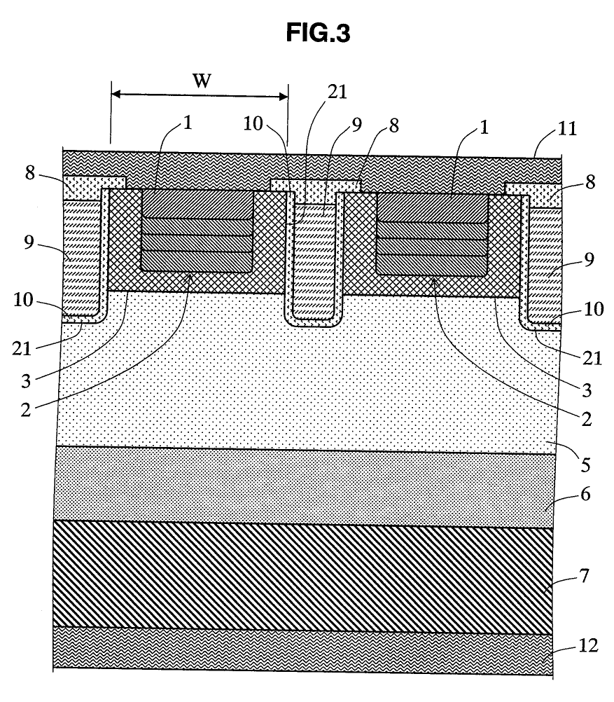

FIG. 1 is a plan view showing a structure of a semiconductor device in accordance with the first embodiment of the present invention. FIG. 2 is a cross-sectional view taken along a line A-A in FIG. 1, and FIG. 3 is a cross-sectional view taken along a line B-B in FIG. 1. FIGS. 1 to 3 are schematic views and the components are not shown in their actual scale ratios. Further, FIGS. 2 and 3 illustrate an example of a vertical type semiconductor device, wherein an emitter electrode and a collector electrode are respectively formed on different surfaces.

As shown in FIGS. 2 and 3, the semiconductor device according to the present embodiment is provided with a base layer 5 consisting of an N-type impurity region. A collector layer 7 consisting of a high concentration P-type impurity region is formed below the base layer 5 with a buffer layer 6 consisting of a high concentration N-type impurity region interposed therebetween. A collector electrode 12 is connected to the collector layer 7.

In the meantime, a plurality of trenches 21 (trench formed regions) is formed with a given interval width W in the base layer 5. In the top portion of the base layer 5, a body layer 3 consisting of a P-type impurity region is provided in contact with the trenches 21. A gate electrode 9 made of polysilicon and the like is filled in the each trench 21 with a gate insulating film 10 made of an oxide film and the like interposed therebetween. As shown in FIG. 1, the each gate electrode 9 (trench 21) is continuously formed in a direction perpendicular to the sheets in FIGS. 2 and 3.

As shown in FIGS. 1 and 2, emitter layers 4 consisting of high concentration N-type impurity regions are formed in contact with the trenches 21 in portions on the surface of the body layer 3. The each emitter layer 4 is provided intersecting with the gate electrodes 9 as shown in FIG. 1.

As shown in FIGS. 1 and 3, contact layers 1 consisting of high concentration P-type impurity regions are formed spaced from the trenches 21 in portions on the surface of the body layer 3. As shown in FIG. 1, the each contact layer 1 is provided in parallel with the each gate electrode 9. The contact layers 1 and the gate electrodes 9 are alternately arranged.

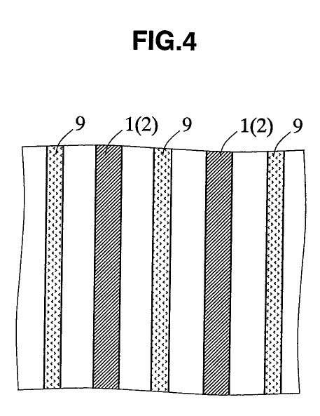

FIG. 4 is a plan view illustrating a plan structure of the gate electrodes 9 and the contact layers 1 in the IGBT. As shown in FIG. 4, the contact layers 1 are formed in the regions as well where the emitter layers 4 are formed. Thus, in the present embodiment, in the region where the emitter layer 4 and the contact layer 1 are overlapped one another, the contact layer 1 is arranged just below the emitter layer 4 as shown in FIG. 2. In this case, when the contact layer 1 is formed in contact with the trench 21, an impurity concentration is changed in the region where an inversion layer (a channel) of the above-described MOS transistor is constituted, and that allows fluctuation of a threshold voltage in the IGBT. Therefore, the contact layers 1 are arranged spaced from the trenches 21 in the present embodiment.

In the IGBT as shown in FIGS. 1 to 3, an emitter electrode 11, which is electrically connected to both the emitter layers 4 and contact layers 1, is provided on the top of the emitter layers 4 and the contact layers 1. The gate electrodes 9 and the emitter electrode 11 are electrically insulated as oxide films 8 are interposed between the each gate electrode 9 and the emitter electrode 11.

The IGBT according to the present embodiment comprises buried layers 2 consisting of P-type impurity regions which are formed spaced from the trenches 21 within the body layer 3. The impurity concentration peak position of the each buried layer 2 is deeper than that of the corresponding contact layer 1. It is preferable that the each buried layer 2 has a higher concentration than the body layer 3, and is formed from the upper portion to the lower portion in the body layer 3. The buried layers 2 are, for example, formed by performing ion implantations of P-type impurity material several times using different energies respectively. As shown in FIGS. 1 to 4, the each buried layer 2 is formed directly below the each contact layer 1 having the same plane structure as the corresponding contact layer 1. The buried layers 2 may be formed by using the same photomask used for an ion implantation to form the contact layers 1. The each buried layer 2 may have a different plane structure with the corresponding contact layer 1. For example, the buried layer 2 may have a different width from the corresponding contact layer 1 in plane view.

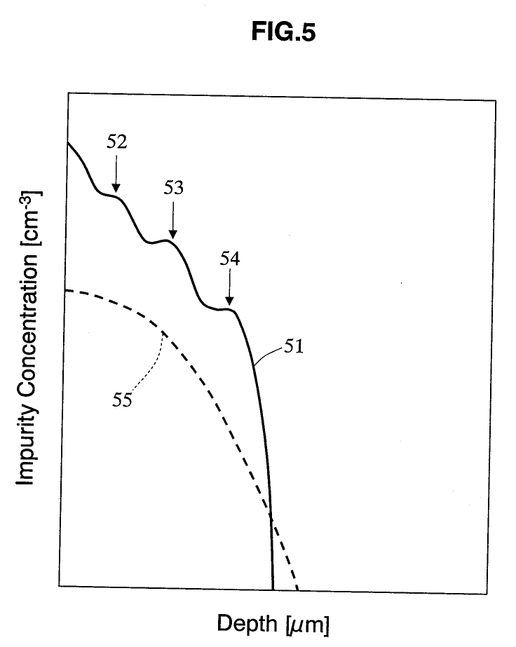

FIG. 5 is a diagram illustrating profiles for an impurity concentration in the buried layer 2 and the body layer 3. In FIG. 5, a depth from the surface of the body layer 3 is in a horizontal axis and the P-type impurity concentration is in a vertical axis. A profile 51 indicated by a solid line illustrates a profile for the impurity concentration in the region including the buried layer 2. A profile 55 indicated by a broken line illustrates a profile for the impurity concentration in the region excluding the buried layer 2, i.e., a region between the buried layer 2 and the trench 21 in the body layer 3 as shown in FIGS. 2 and 3.

According to the present embodiment, the buried layer 2 is formed by boron ion-implantations with three kinds of different implantation energies one another. For example, ions are implanted at several tens of keV implantation energies for forming shallow portions of the buried layer 2, and at several hundreds of keV to several MeV implantation energies for forming deep portions thereof.

The profile 51 has its peeks 52, 53 and 54 of the impurity concentration corresponding to respective implantation energies. The profile 51 has higher impurity concentrations than the profile 55. In the conventional structure, the impurity concentration in the body layer 3 is the same as the profile 55 as the buried layer 2 is not existed.

According to the present embodiment, the each buried layer 2 is formed spaced from the trenches 21. Thus, even when the buried layer 2 is formed, a state on a boundary between the body layer 3 and the each gate insulating film 10 is the same as the conventional structure. Namely, according to the present embodiment, the impurity concentration in the body layer 3 can be raised without fluctuating the threshold voltage of the IGBT. As a result, resistance component in the P-type impurity region composed of the body layer 3, the buried layer 2 and the contact layer 1 (hereinafter referred to as a body region) may be lowered as compared with the conventional structure. Therefore, potential rise in the body region is suppressed by hole current which flows during the operation of the IGBT, and thereby a value of the hole current by which the parasitic thyristor turns on-state become large as compared with the conventional structure.

Preferably, the each buried layer 2 may be formed in deeper position within the body layer 3 with higher concentration. Adopting such structure, positions where breakdown is occurred, which determine the collector-emitter breakdown voltage in the IGBT, may be different from the bottom corners of the trenches wherein breakdown is occurred in the conventional structure.

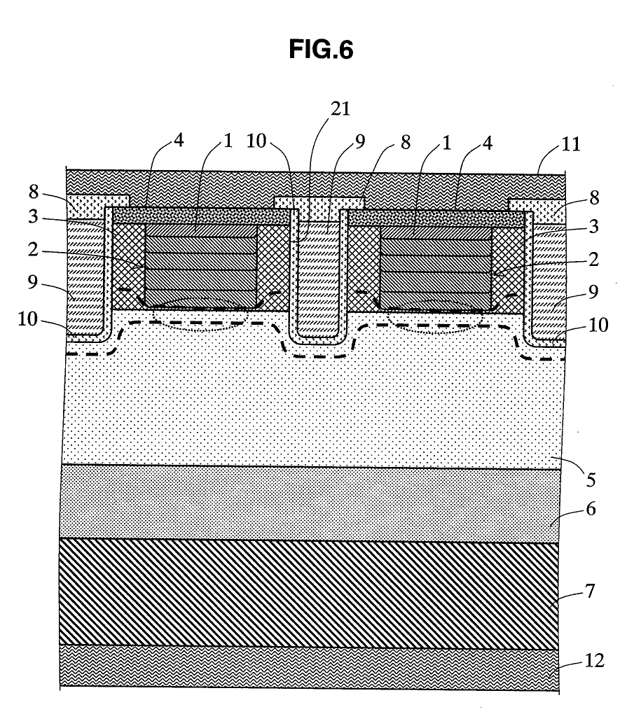

FIG. 6 is a schematic view showing a depletion layer formed in a boundary between the body layer 3 wherein the buried layers 2 are formed and the base layer 5 when the bottom portion of the each buried layer 2 is provided adjacent to the bottom portion of the body layer 3. Edges of the depletion layer are illustrated by broken lines in FIG. 6.

When the bottom portion of the each buried layer 2 is provided adjacent to the bottom portion of the body layer 3, the depletion layer hardly extends toward the body layer 3 due to the existence of the buried layer 2 as shown in FIG. 6. Therefore, a breakdown voltage is lowered in the PN junction (shown by dotted lines in FIG. 6) composed of the body layer 3 wherein the buried layer 2 is formed and the base layer 5.

By disposing the buried layer 2 in order that the breakdown voltage of the PN junction is lower than that of the bottom corners of trenches 21, breakdown is firstly occurred in the PN junction when potential is applied to the collector electrode 12 and the emitter electrode 11 to evaluate the collector-emitter breakdown voltage in the IGBT. In such a case, breakdown is not occurred in the bottom corners of the trenches 21. Namely, when potential is applied in order to evaluate the collector-emitter breakdown voltage, hot carriers do not enter the gate insulating film 10. As a result, degradation of reliability of the gate insulating film 10 caused by carrier trap and the destruction thereof can be prevented.

Consequently, the degradation of the IGBT can be prevented by disposing the buried layers 2 in order that the breakdown voltage in the PN junction composed of the body layer 3 wherein the buried layer 2 is formed and the base layer 5 is lower than that between the bottom corners of the trenches 21 and the base layer 5.

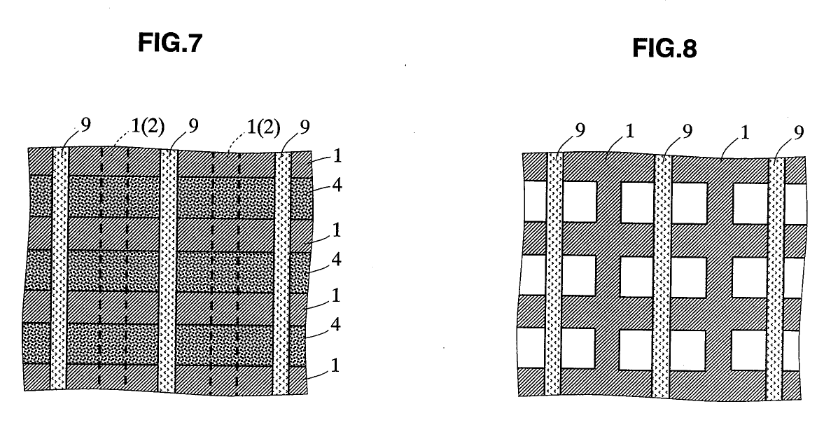

Further, the contact layers 1 and the buried layers 2 may have different plane structure as compared with FIG. 1. FIG. 7 is a plan view showing a modified example of a semiconductor device in the present embodiment. Dispositions of the contact layers 1 in the plane structure as shown in FIG. 7 are different as compared with FIG. 1.

As shown in FIG. 7, the contact layers 1 are formed spaced from the trenches 21 in this example. Then, the contact layers 1 are disposed not only in parallel directions with the gate electrodes 9 but also in directions intersecting with the gate electrodes 9 between the emitter layers 4.

FIG. 8 is a plan view showing a structure of the contact layers 1 and the gate electrodes 9 only shown in FIG. 7. As shown in FIG. 8, the contact layers 1 are disposed between the trenches 21 and between the emitter layers 4.

The buried layers 2 are formed spaced from the trenches 21 and the each buried layer is provided in parallel with the gate electrodes 9, which is the same structure as FIG. 1. The buried layers 2 and the gate electrodes 9 are arranged alternately.

By disposing the contact layers 1 in such a manner, an area of the contact layers 1 exposing on the surfaces of the body layer 3 is increased as compared with the example as shown in FIG. 1. As described above, the body layer 3 is connected to the emitter electrode 11 via the contact layers 1, and the emitter layers 4 as well are connected to the emitter electrode 11. An area on the surface of the body layer 3 where the current potential is the same as the emitter layer 4 is much larger in this example than in the example as shown in FIG. 1. Therefore, fluctuation in potential in the body region occurred by hole current is more suppressed than the example as shown in FIG. 1. As a result, the normal operation of the IGBT is maintained until a current value reaches much larger value without letting a parasitic thyristor turn on.

As explained above, according to the present embodiment, potential rise in the body region during the operation of the IGBT is suppressed without fluctuating threshold potential thereof. As a result, the normal operation of the IGBT can be maintained until the current value reaches much larger than in the conventional structure.

Further, the degradation of the IGBT can be prevented by providing the buried layer in a state that the breakdown voltage in the PN junction composed of the body layer wherein the buried layer 2 is formed and the base layer 5 is lower than the breakdown voltage between the bottom corners of the trenches 21 and the base layer 5.

Furthermore, in FIGS. 2, 3 and 5 of the present embodiment, the impurity distribution (the impurity distribution profile) of the buried layer is present only within the body layer. However, a part of the impurity distribution of the buried layer may reach the base layer.

### Second Embodiment

In the first embodiment, the structure wherein the contact layers and the buried layers are arranged spaced from the trenches has been described. However, depending on conditions to form the contact layers, the contact layers are formed in contact with the trenches. Then, in the second embodiment of the present invention, a semiconductor device wherein the contact layers are formed in contact with the trenches will be described.

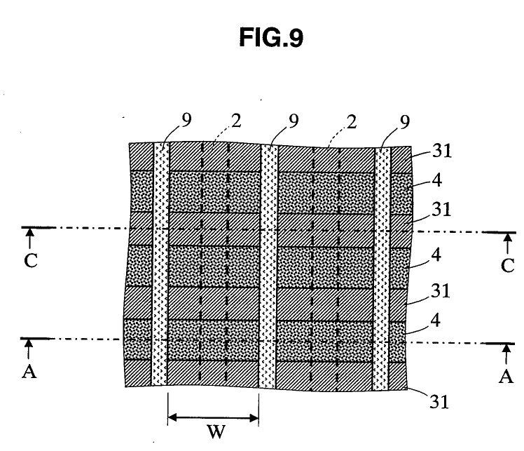

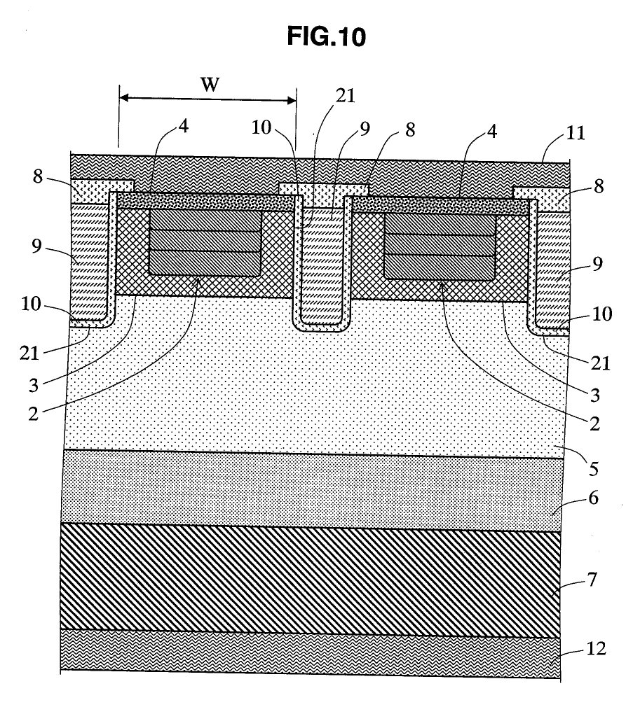

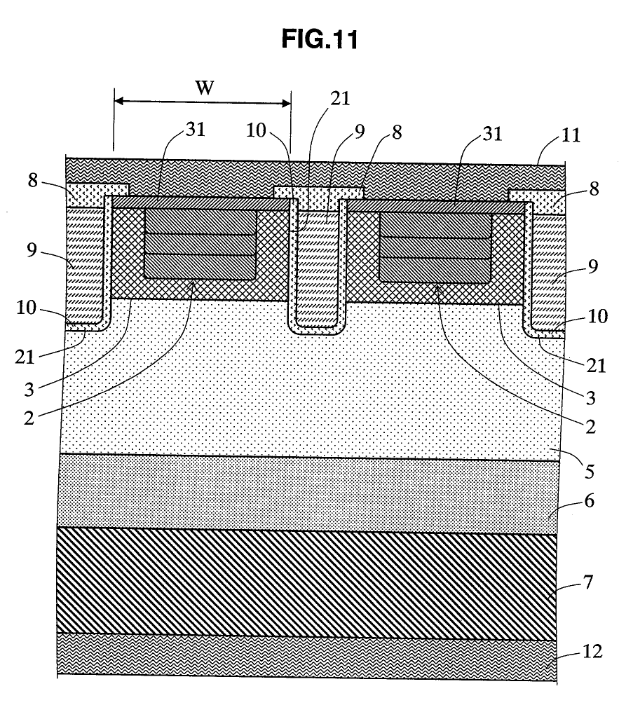

FIG. 9 is a plan view showing a structure of the semiconductor device in accordance with the present embodiment. FIG. 10 is a cross-sectional view taken along a line A-A in FIG. 9 and FIG. 11 is a cross-sectional view taken along a line C-C in FIG. 9. FIGS. 9 to 11 are schematic views and the components are not shown in their actual scale ratios. In FIGS. 10 and 11, a vertical type semiconductor device wherein an emitter electrode and a collector electrode are formed on different surfaces is exemplified. In FIGS. 9 to 11, the same reference numerals as used in the first embodiment are used for indicating the same components.

Contact layers 31 in accordance with the present embodiment are thinner in thickness than emitter layers 4 and are smaller in surface concentration than the emitter layers 4. Thus, in regions where the emitter layer 4 overlap the contact layer 31, the N-type emitter layer 4 completely compensate for the P-type contact layer 31. That is, as shown in FIG. 10, in the regions where the emitter layer 4 overlap the contact layer 31, the contact layer 31 is eliminated. Then, even when the contact layer 31 is formed in contact with the trenches 21, a threshold voltage in an IGBT does not fluctuate. Therefore, as the contact layers 31 can be provided in contact with the trenches 21 as shown in FIG. 11, the present embodiment is different from the first embodiment.

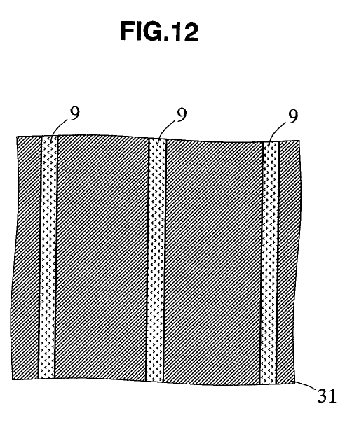

FIG. 12 is a plan view showing a structure of gate electrodes 9 and the contact layers 31 in the IGBT. As shown in FIG. 12, the contact layers 31 are formed on entire main surfaces of body layer 3 including regions to form the emitter layers 4, which is different from the first embodiment. In this case, the regions where the emitter layers 4 are formed turn to the emitter layers 4, and regions between the emitter layers 4 are the contact layers 31.

Since other structures in the present embodiment are the same as those in the first embodiment, explanations thereof are not repeated here.

According to this structure, an area of the contact layers 31 exposed on the surface of the body layer 3 is increased as compared with the first embodiment, and thereby resistance values on the body region are lowered as compared with the first embodiment. As a result, potential rise occurred by hole current can be suppressed. Thus, the normal operation of the IGBT can be maintained until the current value reaches much larger value than in the first embodiment. In addition, as described above, the structure in the present embodiment has no effect on the threshold voltage in the IGBT.

Further, since the contact layers 31 are formed on the entire main surface of the body layer 3, even when a lateral misalignment between the contact layers 31 and the emitter layers 4 is occurred, the characteristics thereof are not changed. On the contrary, according to the modified example of the plane structure described in the first embodiment, when the a lateral misalignment between the contact layers 1 and the emitter layers 4 is occurred, the area of the emitter layers 4 is decreased. Namely, according to the present embodiment, since the area of the contact layers 31 exposing on the surface of the body layer 3 is invariable, an effect of a decrease in potential within the body region is obtained with stability.

As described in the first embodiment, in the present embodiment as well, the buried layers 2 are provided in a state that the breakdown voltage in the PN junction composed of the body layer 3 wherein the buried layers 2 are formed and the base layer 5 is lower than the breakdown voltage between the bottom corners of the trenches 21 and the base layer 5. Thus, degradation of the IGBT can be prevented.

Furthermore, in the present embodiment, the contact layers 31 are formed on the entire surface of the body layer 3, however, the same effect can be obtained even when the each contact layer is formed in a region which is surrounded by the trenches and the emitter layers and in a region including a portion of the emitter layer (especially, in peripheral part).

### Third Embodiment

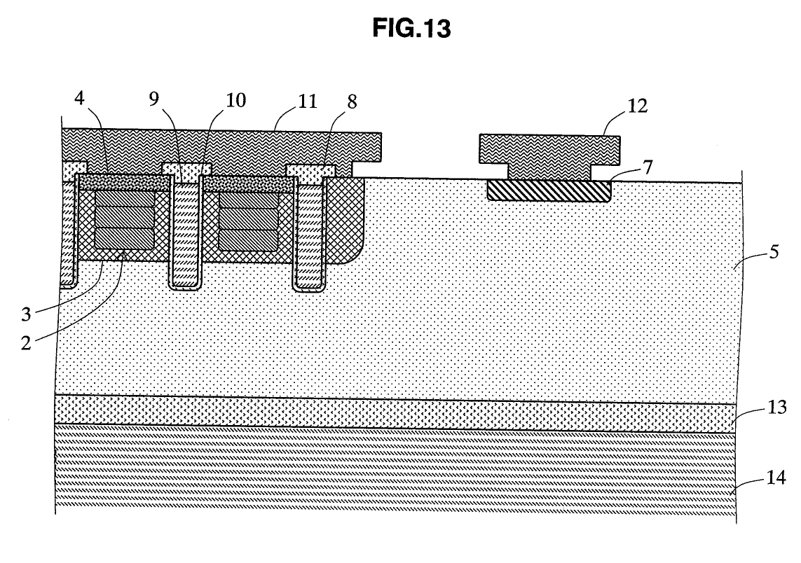

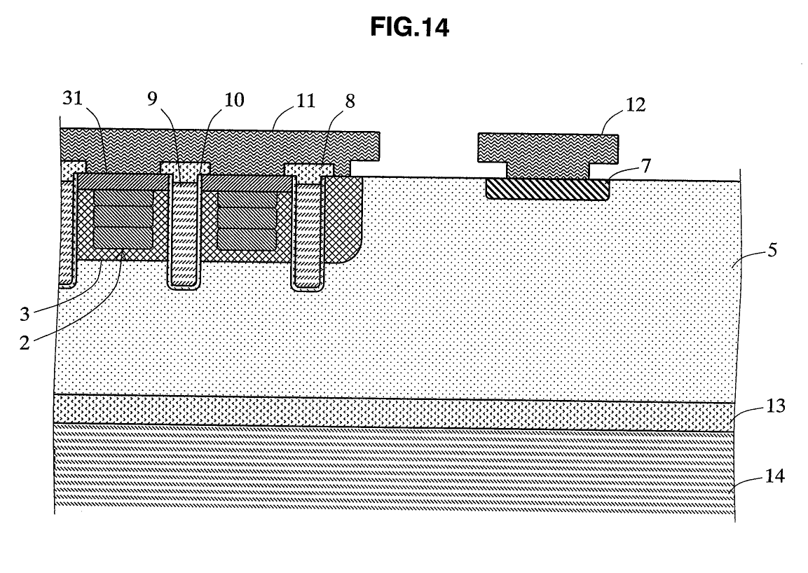

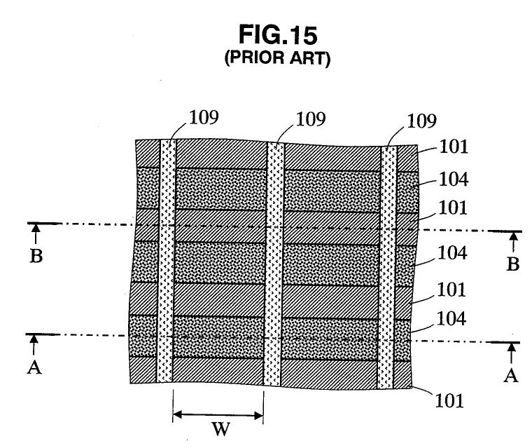

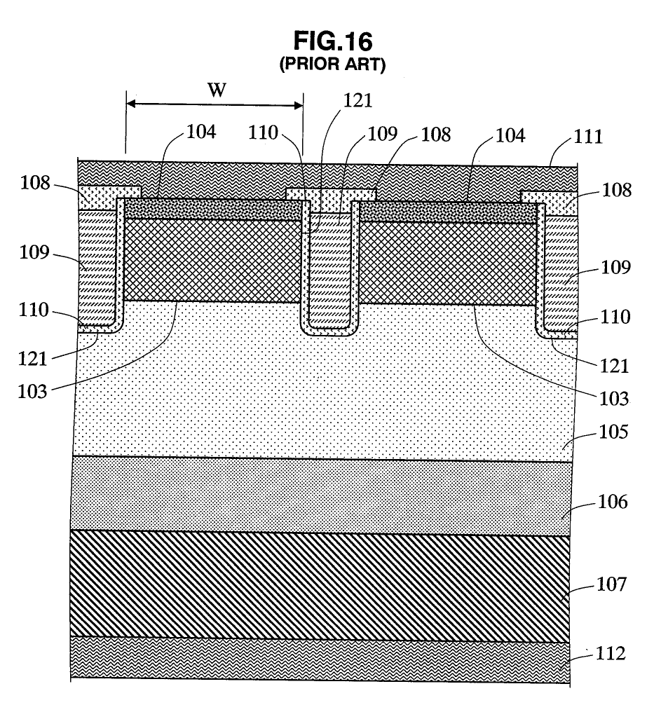

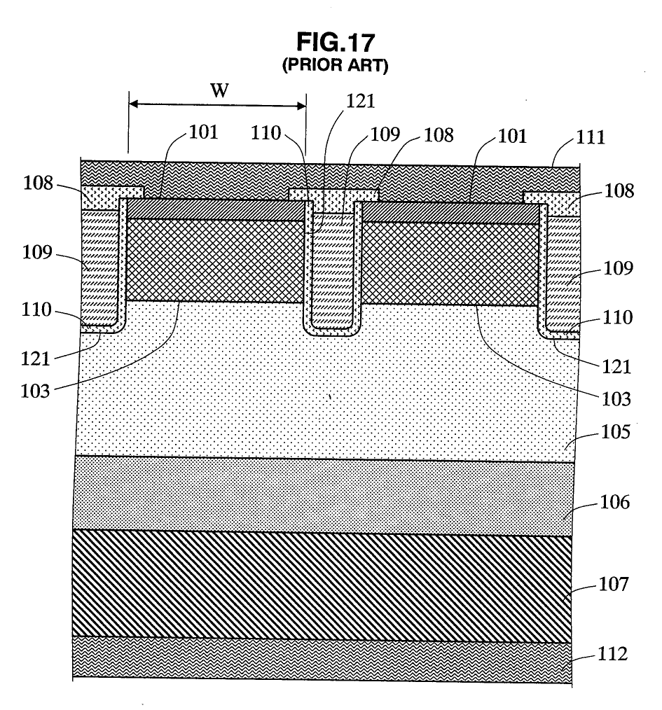

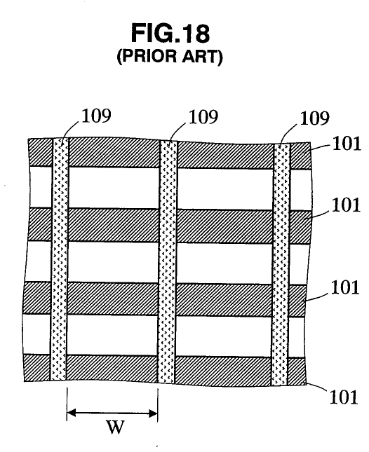

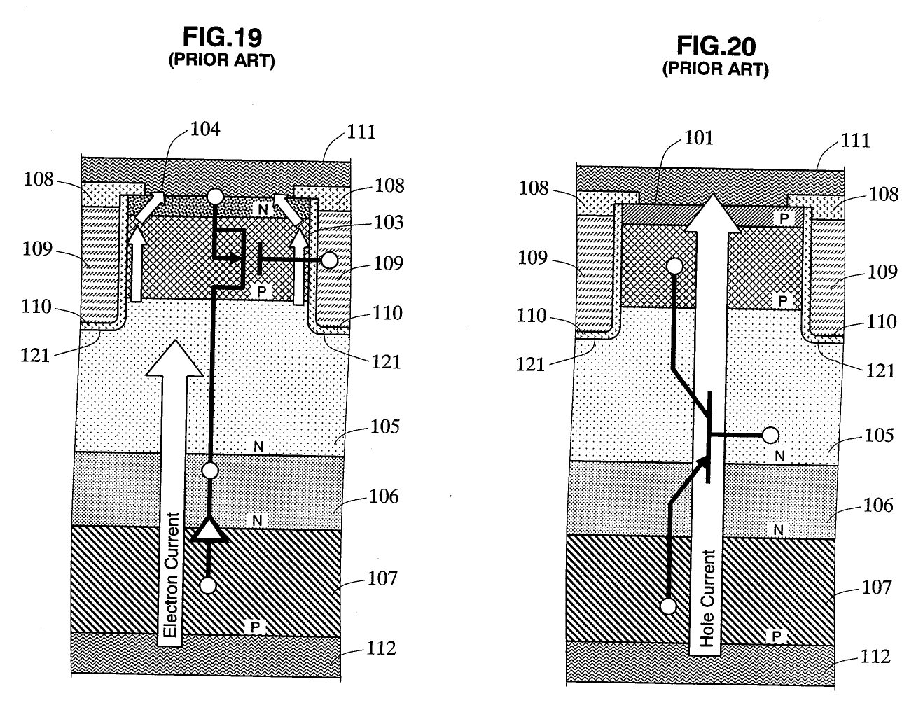

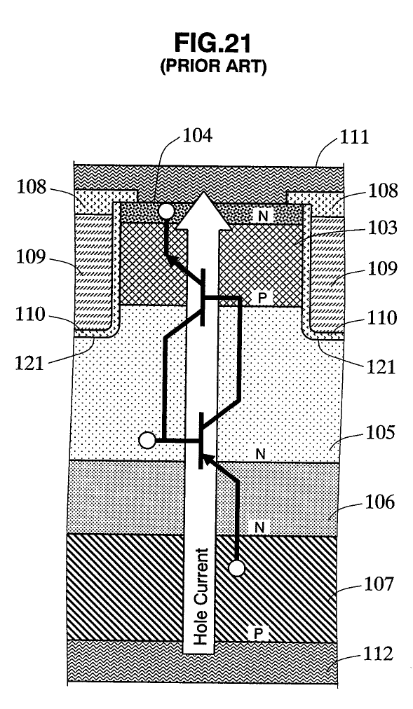

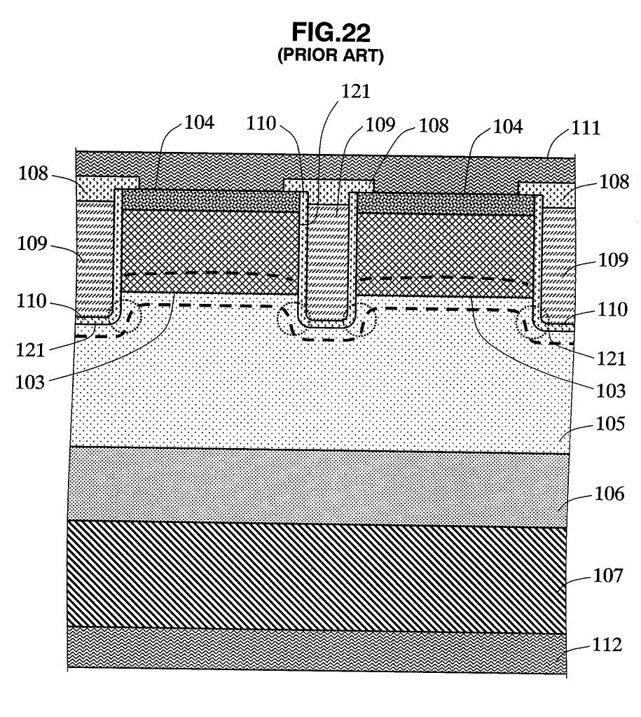

In the first and second embodiments, descriptions have been made with respect to the vertical semiconductor device wherein the emitter electrode and the collector electrode are formed on the different surfaces. On the other hand, the present invention is applicable for a lateral semiconductor device wherein the emitter electrode and the collector electrode are formed on the same surface. FIGS. 13 and 14 are cross-sectional views showing structures of a semiconductor device in the present embodiment. FIG. 13 is a cross-sectional view taken along a line A-A in FIG. 9, and FIG. 14 is a cross-sectional view taken along a line C-C in FIG. 9. Although FIGS. 13 and 14 illustrate examples of the structures described in the second embodiment, the structure described in the first embodiment can be applicable. In FIGS. 13 and 14, the same reference numerals as used in the second embodiment are used for indicating the same components.

As shown in FIGS. 13 and 14, in the semiconductor device in accordance with the present embodiment, a base layer 5 is provided on a P-type silicon substrate 14 with an element isolation film like oxide film interposed therebetween. The body layer 3 is formed in portions on the surface of the base layer 5, and a collector layer 7 is formed in another portion on the surface of the base layer 5. Other structures in the present embodiment are the same as those in the second embodiment.

According to the present embodiment, the effects described in the first and second embodiments are obtained in the lateral semiconductor device.

In the above described embodiments, only specific examples have been described, and technical ranges of the present invention are not limited thereto. Various modifications and applications of the present invention can be made without departing from the scope of the technical idea of the present invention. For example, in the above-described embodiments, each trench is arranged in parallel in plane view, however, the any arrangement is applicable as long as each trench is spaced from one another. Further, any arrangement of the buried layer is applicable other than a parallel arrangement with the trenches, as long as the buried layer is spaced from the each trench (the each gate electrode).

The present invention contributes to an enhancement of ruggedness of an IGBT and is useful for a semiconductor device.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device including an insulated gate bipolar transistor, comprising:
a base layer of a first conductivity type impurity region;
a trench formed region formed within the base layer;
a gate insulating film and a gate electrode formed within the trench formed region;
a body layer of a second conductivity type impurity region formed in contact with the trench formed region within the base layer;
an emitter layer of the first conductivity type impurity region formed on a main surface of the body layer;
a contact layer of the second conductivity type impurity region formed spaced from the trench formed region on the main surface of the body layer; and
a buried layer of the second conductivity type impurity region formed spaced from the trench formed region in the body layer, and an impurity concentration peak position of the buried layer is deeper than an impurity concentration peak position of the contact layer.

2. A semiconductor device according to claim 1, wherein the buried layer is provided in a state that a breakdown voltage of a PN junction composed of the body layer wherein the buried layer is formed and the base layer is lower than a breakdown voltage between a bottom corner of the trench formed region formed within the base layer and the base layer.

3. A semiconductor device according to claim 1, wherein, in plane view of the main surface, a plurality of the trench formed regions is disposed spaced from one another;
the contact layer is disposed in each space between the trench formed regions without intersecting with the trench formed regions;
the buried layer is disposed in each space between the trench formed regions without intersecting with the trench formed regions; and
a plurality of the emitter layers is disposed spaced from one another in a direction intersecting with the trench formed regions, the contact layer and the buried layer.

4. A semiconductor device according to claim 2, wherein, in plane view of the main surface, a plurality of the trench formed regions is disposed spaced from one another;
the contact layer is disposed in each space between the trench formed regions without intersecting with the trench formed regions;
the buried layer is disposed in each space between the trench formed regions without intersecting with the trench formed regions; and
a plurality of the emitter layers is disposed spaced from one another in a direction intersecting with the trench formed regions, the contact layer and the buried layer.

5. A semiconductor device according to claim 1, wherein, in plane view of the main surface, a plurality of the trench formed regions is disposed spaced from one another;
the buried layer is disposed in each space between the trench formed regions without intersecting with the trench formed regions;
a plurality of the emitter layers is disposed spaced from one another in a direction intersecting with the trench formed regions and the buried layer; and
the contact layer is disposed in each space between the trench formed regions and between the emitter layers.

6. A semiconductor device according to claim 2, wherein, in plane view of the main surface, a plurality of the trench formed regions is disposed spaced from one another;
the buried layer is disposed in each space between the trench formed regions without intersecting with the trench formed regions;
a plurality of the emitter layers is disposed spaced from one another in a direction intersecting with the trench formed regions and the buried layer; and
the contact layer is disposed in each space between the trench formed regions and between the emitter layers.

7. A semiconductor device including an insulated gate bipolar transistor, comprising:
a base layer of a first conductivity type impurity region;
a trench formed region formed within the base layer;
a gate insulating film and a gate electrode formed within the trench formed region;
a body layer of a second conductivity type impurity region formed in contact with the trench formed region within the base layer;
an emitter layer of the first conductivity type impurity region formed on a main surface of the body layer;
a contact layer of the second conductivity impurity region formed on the main surface of the body layer in a state that the contact layer is thinner in thickness than the emitter layer, and has a surface concentration smaller than the emitter layer; and
a buried layer of the second conductivity type impurity region formed spaced from the trench formed region in the body layer, and an impurity concentration peak position of the buried layer is deeper than an impurity concentration peak position of the contact layer.

8. A semiconductor device according to claim 7, wherein the buried layer is provided in a state that a breakdown voltage of a PN junction composed of the body layer wherein the buried layer is formed and the base layer is lower than a breakdown voltage between a bottom corner of the trench formed region formed within the base layer and the base layer.

9. A semiconductor device according to claim 7, wherein, in plane view of the main surface, a plurality of the trench formed regions is disposed spaced from one another;
the buried layer is disposed in each space between the trench formed regions without intersecting with the trench formed regions;
a plurality of the emitter layers is disposed spaced from one another in a direction intersecting with the trench formed regions and the buried layer; and
the contact layer is disposed in a region surrounded by the trench formed regions and the emitter layers, and in a region including a portion of the emitter layer or the entire emitter layer.

10. A semiconductor device according to claim 8, wherein, in plane view of the main surface, a plurality of the trench formed regions is disposed spaced from one another;
the buried layer is disposed in each space between the trench formed regions without intersecting with the trench formed regions;
a plurality of the emitter layers is disposed spaced from one another in a direction intersecting with the trench formed regions and the buried layer; and
the contact layer is disposed in a region surrounded by the trench formed regions and the emitter layers, and in a region including a portion of the emitter layer or the entire emitter layer.

11. A semiconductor device according to claim 1, further comprising:
a collector layer of the second conductivity type impurity region formed on opposite side of the body layer.

12. A semiconductor device according to claim 2, further comprising:
a collector layer of the second conductivity type impurity region formed on opposite side of the body layer.

13. A semiconductor device according to claim 7, further comprising:
a collector layer of the second conductivity type impurity region formed on opposite side of the body layer.

14. A semiconductor device according to claim 8, further comprising:
a collector layer of the second conductivity type impurity region formed on opposite side of the body layer.

15. A semiconductor device according to claim 1, further comprising:
an element isolation film formed adjacent to the base layer on opposite side of the body layer in the depth direction; and
a collector layer of the second conductivity type impurity region formed apart from the body layer on the same side of the body layer.

16. A semiconductor device according to claim 2, further comprising:
an element isolation film formed adjacent to the base layer on opposite side of the body layer in the depth direction; and
a collector layer of the second conductivity type impurity region formed apart from the body layer on the same side of the body layer.

17. A semiconductor device according to claim 7, further comprising:
an element isolation film formed adjacent to the base layer on opposite side of the body layer in the depth direction; and
a collector layer of the second conductivity type impurity region formed apart from the body layer on the same side of the body layer.

18. A semiconductor device according to claim 8, further comprising:
an element isolation film formed adjacent to the base layer on opposite side of the body layer in the depth direction; and
a collector layer of the second conductivity type impurity region formed apart from the body layer on the same side of the body layer.
